(19) United States
(12) Patent Application Publication
(10) Pub. No.: US 2025/0293667 A1
(43) Pub. Date: Sep. 18, 2025

(54) WAFER-LEVEL PACKAGED RESONATOR AND PREPARATION METHOD THEREOF, AND ELECTRONIC EQUIPMENT

(71) Applicant: TKD Science and Technology Co., LTD., Suizhou (CN)

(72) Inventors: Yang WAN, Suizhou (CN); Xiaowei ZHANG, Suizhou (CN); Kang PENG, Suizhou (CN); Mingfan LIU, Suizhou (CN); Jiahao ZHANG, Suizhou (CN)

(21) Appl. No.: 19/002,744

(22) Filed: Dec. 27, 2024

(30) Foreign Application Priority Data
Mar. 14, 2024 (CN) 202410290709.3

(51) Int. Cl. H03H 9/17; H03H 3/02; H03H 9/05; H03H 9/13

(52) U.S. Cl. CPC H03H 9/17; H03H 3/02; H03H 9/05; H03H 9/13

(57) ABSTRACT

The present application provided a wafer-level packaged resonator and a preparation method therefor, as well as an electronic equipment, relating to the technical field of resonators. The electronic equipment includes a wafer-level packaged resonator. The wafer-level packaged resonator includes a quartz blank, both sides of which are provided with a first electrode and a second electrode respectively; a first packaging substrate, packaged on one side of the quartz blank provided with the first electrode, and a first solder pad and a second solder pad are provided with intervals on the side of the first packaging substrate away from the quartz blank; a second packaging substrate, packaged on the other side of the quartz blank, and a third solder pad and a fourth solder pad are provided on the side of the second packaging substrate away from the quartz blank.

### CROSS-REFERENCE TO RELATED APPLICATIONS

The present application is based upon and claims priority to Chinese patent application No. 202410290709.3, filed on Mar. 14, 2024, the entire content of which is incorporated herein by reference.

### TECHNICAL FIELD

The present application relates to the technical field of resonators, and in particular to a wafer-level packaged resonator and preparation method thereof, and an electronic equipment.

### BACKGROUND

Conventional quartz crystal resonator structures typically consist of a metal top cover, a quartz blank, and a ceramic base, and are packaged by vacuum or inert gas. The quartz blank is made in full plate by photolithography process, then folded off one by one, connected with the ceramic base pin through conductive adhesive, and finally packaged with the metal top cover by roll welding. The whole fabricating process is completed individually, leading to low packaging efficiency and reduced reliability.

With the rapid development of mobile communication electronics, the demand for miniaturization of devices is increasing, and the miniaturization of the resonators is also imperative. Wafer-level fabrication can achieve significant reduction in manufacturing cost of a single resonator as well as quality control consistency between resonators: In general, the larger the wafer size, the lower the manufacturing cost of a single resonator. A wafer-level packaged quartz resonator and its manufacturing method are disclosed in relevant documents. The quartz resonator includes: a quartz piezoelectric layer, a first packaging substrate, and a second packaging substrate. A first electrode and a second electrode are provided on both sides of the quartz piezoelectric layer. The first packaging substrate and the second packaging substrate are respectively provided on one side and the other side of the piezoelectric layer. The first packaging substrate is opposite to the first electrode, and the second packaging substrate is opposite to the second electrode, wherein: the electrode lead-out end of the first electrode includes a first external connecting part that at least extends to the side of the second packaging substrate away from the second electrode through an end face of the second packaging substrate, or the electrode lead-out end of the second electrode includes a second external connecting part that at least extends to the side of the first packaging substrate away from the first electrode through an end face of the first packaging substrate.

With respect to the above related art, there are still problems such as the need for installing external connecting part to a single blank lead to low packaging efficiency, and the need to identify the back solder pads during final inspection, resulting in low test efficiency.

### SUMMARY

In order to improve the packaging and the final inspection efficiency, an objective of the present application is to provide a wafer-level packaged resonator and a preparation method thereof, and an electronic equipment.

In a first aspect, a wafer-level packaged resonator provided by the present application employs the following technical solution:

A wafer-level packaged resonator, including:

A quartz blank, both sides of which are provided with a first electrode and a second electrode respectively;

A first packaging substrate, packaged on one side of the quartz blank provided with the first electrode, and a first solder pad and a second solder pad are provided with intervals on the side of the first packaging substrate away from the quartz blank;

A second packaging substrate, packaged on the other side of the quartz blank, and a third solder pad and a fourth solder pad are provided on the side of the second packaging substrate away from the quartz blank;

One position of the first solder pad extends through the first packaging substrate and is electrically connected with the electrode lead-out end of the first electrode. The other position of the first solder pad extends through the first packaging substrate, the quartz blank, and second packaging substrate in sequence and is electrically connected with the third solder pad;

One position of the second solder pad extends through the first packaging substrate and is electrically connected with the electrode lead-out end of the second electrode. The other position of the second solder pad extends through the first packaging substrate, the quartz blank, and second packaging substrate in sequence and is electrically connected with the fourth solder pad;

By adopting the above technical solutions, firstly, the first electrode and the second electrode of the quartz blank are introduced into the front side of the first packaging substrate, and then into the reverse side of the second packaging substrate, ensuring that the product parameters can be tested on both sides of a single product of the wafer-level packaged resonator, and there is no need to turn over the product to identify the back solder pads during the final inspection, which improves the testing efficiency; Secondly, the setting of the first solder pad and the second solder pad of the first packaging substrate can be expanded to realize the integrated manufacturing of the oscillator; In addition, on the basis of wafer-level packaging, there is no need to set up an external connecting parts, and the finished product can be obtained after packaging cutting, which improves the packaging efficiency.

Alternatively, the quartz blank includes a resonant part, a packaging part surrounded on the periphery of the resonant part, and a connecting beam between the resonant part and the packaging part. The first electrode and the second electrode are respectively arranged on both sides of the resonant part;

Both sides of the packaging part, a side of the first packaging substrate opposite to the packaging part, and a side of the second packaging substrate opposite to the packaging part are provided with bonded metal layers, and the projection of the bonded metal layers overlaps along the thickness direction of the packaging part;

The electrode lead-out ends of the first electrode and the second electrode are both led out to the packaging part through the connecting beam, and are inside the bonded metal layer.

By adopting the above technical solutions, the electrode lead-out ends of the first electrode and the second electrode are located inside the bonded metal layer, that is, the test position of the quartz blank is constructed inside the packaging part, so that there is no need to additionally set up test positions outside the quartz blank, which improves the product integration, and allows for more quartz blanks to be arranged on the whole quartz wafer, thus obtaining more resonators under the condition of the same quartz wafer size and reducing the manufacturing cost of a single resonator.

Alternatively, the packaging part is provided with a first through-hole penetrating through it, and the first through-hole is located on the lead-out path of the electrode lead-out end of the second electrode. The electrode lead-out end of the second electrode includes:

A transition section, provided opposite to the electrode lead-out end of the first electrode;

A first through-hole metal section, including a connecting layer laid on the sidewall of the first through-hole, an extension layer and an export layer connected with both sides of the connecting layer respectively. The extension layer is electrically connected with the transition section.

By adopting the above technical solutions, the electrode lead-out end of the second electrode is set through a transition section to avoid the position of the packaging part occupied by the electrode lead-out end of the first electrode, so that the electrode lead-out end of the first electrode and the second electrode is misaligned. Furthermore, the end of the electrode lead-out end of the second electrode is led out to the front of the quartz blank through the setting of the first through-hole in coordinate with the first through-hole metal section, so that the electrode lead-out end of the first electrode and the second electrode is arranged on the same side, forming the test position of the quartz blank, which meets the design of synchronously introducing the first electrode and the second electrode of the quartz blank to the front of the first packaging substrate.

Alternatively, the first packaging substrate is provided with a second through-hole penetrating through it, and the second solder pad extends along the sidewall of the second through-hole to the other side of the first packaging substrate to form a first lead-out end. The first lead-out end extends to form a lead-out wire, and the other end of the lead-out wire is opposite to the export layer and is piezoelectric connected.

By adopting the above technical solutions, the second solder pad is led out to the reverse side of the first packaging substrate (the side opposite to the quartz blank) in electrical connection through the second through-hole, and then set up the lead-out wire on the reverse side of the first packaging substrate to achieve the connection between the first lead-out end and the export layer, and then the connection between the second solder pad and the second electrode, introducing the second electrode to the front of the first packaging substrate. Furthermore, the lead-out wire is set as a fold-line to avoid the influence on the first electrode and the second electrode. Specifically, the projection of the lead-out wire along the thickness direction of the packaging part does not intersect with the projection of the first electrode along the thickness direction of the packaging part.

Alternatively, a position of the first packaging substrate opposite to the transition section is provided with a third through-hole penetrating through it, and the first solder pad extends along the sidewall of the third through-hole to the other side of the first packaging substrate to be piezoelectrically connected with the electrode lead-out end of the first electrode.

By adopting the above technical solutions, the first solder pad is led out to the reverse side of the first packaging substrate (the side opposite to the quartz blank) in electrical connection through the third through-hole, and then cooperates with the electrode lead-out end of the first electrode to achieve the connection between the first solder pad and the first electrode, introducing the first electrode to the front of the first packaging substrate.

Alternatively, another part of the first packaging substrate corresponding to the first solder pad is provided with a fourth through-hole penetrating through it, and the first solder pad extends along the sidewall of the fourth through-hole to the other side of the first packaging substrate to form a first annular layer;

The position of the packaging part corresponding to the fourth through-hole is provided with a fifth through-hole penetrating through it, and wraps around the fifth through-hole is provided with a second through-hole metal section. The first annular layer is electrically connected with the second through-hole metal section;

The position of the second packaging substrate corresponding to the fourth through-hole is provided with a sixth through-hole penetrating through it, and the third solder pad extends along the sidewall of the sixth through-hole to the other side of the second packaging substrate to form a second annular layer. The second annular layer is electrically connected with the second through-hole metal section;

By adopting the above technical solutions, the first electrode is introduced into the front of the first packaging substrate and then into the reverse of the second packaging substrate through the setting of the fourth through-hole, the fifth through-hole, and the sixth through-hole successively penetrated along the thickness direction of the resonator, cooperated with the arrangement of the first solder pad (the first annular layer), the second through-hole metal section, and the third solder pad (the second annular layer).

Alternatively, the sixth through-hole and the fourth through-hole are coaxially arranged, the fifth through-hole and the fourth through-hole are set misaligned; The electrical connection with each side of the second through-hole metal section also includes a first dislocation layer, and a pair of the first dislocation layers are respectively piezoelectrically connected with the first annular layer and the second annular layer; The electrical connection with the first annular layer further includes a second dislocation layer, and the electrical connection with the second annular layer also includes a third dislocation layer. The second dislocation layer and the third dislocation layer are respectively electrically connected with both sides of the second through-hole metal section;

By adopting the above technical solutions, staggered piezoelectric connection is realized during the process of introducing the first electrode to the front of the first packaging substrate and then into the reverse of the second packaging substrate, so as to enable staggered connection of the holes between each layer of the first packaging substrate, the quartz blank, and the second packaging substrate when the three layers are bonded, thus can effectively strengthen the interconnection strength of the hole-corresponding-metal and improve reliability.

Alternatively, another part of the first packaging substrate corresponding to the second solder pad is provided with a seventh through-hole penetrating through it, and the second solder pad extends along the sidewall of the seventh through-hole to the other side of the first packaging substrate to form a third annular layer; The packaging part corresponding to the seventh through-hole is provided with an eighth through-hole penetrating through it, and wraps around the eighth through-hole is provided with a third through-hole metal section, and the third annular layer is electrically connected with the third through-hole metal section; The second packaging substrate corresponding to the seventh through-hole is provided with a ninth through-hole penetrating through it, and the fourth solder pad extends along the sidewall of the ninth through-hole to the other side of the second packaging substrate to form a fourth annular layer. The fourth annular layer is electrically connected with the third through-hole metal section;

By adopting the above technical solutions, the second electrode is introduced into the front of the first packaging substrate and then into the reverse of the second packaging substrate through the setting of the seventh through-hole, the eighth through-hole, and the ninth through-hole successively penetrated along the thickness direction of the resonator, cooperated with the arrangement of the second solder pad (the third annular layer), the third through-hole metal section, and the fourth solder pad (the fourth annular layer).

Alternatively, the seventh through-hole and the fifth through-hole are coaxially arranged, the sixth through-hole and the fifth through-hole are set misaligned; The electrical connection with each side of the third through-hole metal section also includes a fourth dislocation layer, and a pair of the fourth dislocation layers are respectively piezoelectrically connected with the third annular layer and the fourth annular layer; The electrical connection with the third annular layer further includes a fifth dislocation layer, and the electrical connection with the fourth annular layer also includes a sixth dislocation layer. The fifth dislocation layer and the sixth dislocation layer are respectively electrically connected with both sides of the third through-hole metal section;

By adopting the above technical solutions, staggered piezoelectric connection is realized during the process of introducing the second electrode to the front of the first packaging substrate and then into the reverse of the second packaging substrate, so as to enable staggered connection of the holes between each layer of the first packaging substrate, the quartz blank, and the second packaging substrate when the three layers are bonded, thus can effectively strengthen the interconnection strength of the hole-corresponding-metal and improve reliability.

Alternatively, the wafer-level packaged resonator further includes a shielding layer arranged on the side of the first packaging substrate away from the quartz blank, and the projection of the first electrode along the thickness direction of the first packaging substrate falls within the projection range of the shielding layer along the thickness direction of the first packaging substrate.

By adopting the above technical solutions, the external electromagnetic interference is shielded through the setting of the shielding cover. Under the premise of meeting the position setting requirements of the first solder pad and the second solder pad, the shielding cover overlaps the first electrode along the thickness direction of the first packaging substrate, so as to improve the shielding effect.

In a second aspect, a preparation method of the wafer-level packaged resonator provided in the present application adopts the following technical solution:

A preparation method of wafer-level packaged resonators includes the following steps:

Prepare a blank wafer including several quartz blanks arranged in arrays;

Prepare a first packaging wafer including several first packaging substrates;

Prepare a second packaging wafer including several second packaging substrates, wherein several first packaging substrates and several second packaging substrates correspond one-to-one with several quartz blanks, respectively;

Stack and bond the second packaging wafer, the blank wafer, and the first packaging wafer in sequence and then cut.

By adopting the above technical solutions, firstly, the product parameters can be tested on both sides of a single product of the wafer-level packaged resonator, and there is no need to turn over the product to identify the back solder pads during the final inspection, which improves the testing efficiency; Secondly, on the basis of wafer-level packaging, there is no need to set up an external connecting parts, and the finished product can be obtained after packaging cutting, which improves the packaging efficiency.

In a third aspect, an electronic equipment provided in the present application adopts the following technical solution:

An electronic equipment including a wafer-level packaged resonator.

By adopting the above technical solutions, an electronic equipment including a wafer-level packaged resonator is provided, which has a high product integration.

In summary, the present application includes at least one of the following beneficial technical effects:

1. Introducing the first electrode and the second electrode of the quartz blank into the front side of the first packaging substrate, and then into the reverse side of the second packaging substrate, ensuring that the product parameters can be tested on both sides of a single product of the wafer-level packaged resonator, and there is no need to turn over the product to identify the back solder pads during the final inspection, which improves the testing efficiency; At the same time, the setting of the first solder pad and the second solder pad of the first packaging substrate can be expanded to realize the integrated manufacturing of the oscillator.

2. The electrode lead-out ends of the first electrode and the second electrode are both located inside the bonded metal layer, that is, the test position of the quartz blank is constructed inside the packaging part, so that there is no need to additionally set up test positions outside the quartz blank, which improves the product integration and reduces the manufacturing cost of a single resonator.

3. Realize wafer-level packaging without the need to set up an external connecting parts, and the finished product can be obtained after packaging cutting, which improves the packaging efficiency.

4. The holes between each layer of the first packaging substrate, the quartz blank, and the second packaging substrate are in staggered connection when the three layers are bonded, thus can effectively strengthen the interconnection strength of the hole-corresponding-metal and improve reliability.

### BRIEF DESCRIPTION OF THE DRAWINGS

FIG. 1 is an exploded schematic diagram for demonstrating a front arrangement of the second packaging substrate, the quartz blank, and the first packaging substrate in Example 1 of the present application;

FIG. 2 is an exploded schematic diagram for demonstrating a front arrangement of the second packaging substrate, the quartz blank, and the first packaging substrate in Example 1 of the present application;

FIG. 3 is a schematic structural diagram of the quartz wafer in Example 1 of the present application;

FIG. 4 is a schematic structural diagram for demonstrating a front side of the quartz blank in Example 1 of the present application;

FIG. 5 is a schematic structural diagram for demonstrating a reverse side of the quartz blank

in Example 1 of the present application;

FIG. 6 is an exploded schematic diagram of the first packaging substrate in Example 1 of the present application;

FIG. 7 is an exploded schematic diagram of the second packaging substrate in Example 1 of the present application;

### DESCRIPTION OF THE REFERENCE NUMERALS

1, quartz wafer; 10, alignment marks; 11, cutting channel;
2, second packaging substrate; 20, sixth through-hole; 21, ninth through-hole; 22, fourth thru-hole; 23, sixth thru-hole;
30, third solder pad; 300, second annular layer; 301, third dislocation layer; 31, fourth solder pad; 310, fourth annular layer; 311, sixth dislocation layer; 32, fifth solder pad; 33, sixth solder pad; 34, display hole;
4, quartz blank; 40, bonded metal layer;
5, resonant part; 50, first electrode; 51, contact point A; 52, second electrode; 53, transition section; 54, first through-hole metal section; 55, connecting layer; 56, extension layer; 57, export layer;
6, packaging part; 60, first through-hole; 61, fifth through-hole; 62, second through-hole metal section; 63, first dislocation layer; 64, eighth through-hole; 65, third through-hole metal section; 66, fourth dislocation layer; 67, third thru-hole; 68, fifth thru-hole;
7. connecting beams;
8, first packaging substrate; 80, second through-hole; 81, third through-hole; 82, fourth through-hole; 83, seventh through-hole; 84, first thru-hole; 85, second thru-hole;
9, first solder pad; 90, contact point B; 91, first annular layer; 92, second dislocation layer; 93, third annular layer; 94, fifth dislocation layer; 95, second solder pad; 96, first lead-out end; 97, lead-out wire; 98, shielding layer.

### DETAILED DESCRIPTION OF THE EMBODIMENTS

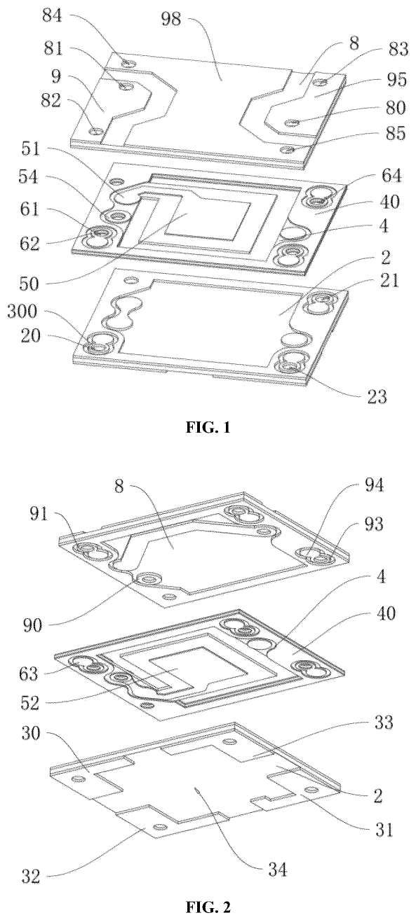

The present application is further described in detail below in conjunction with FIG. 1-FIG. 7.

### Example 1

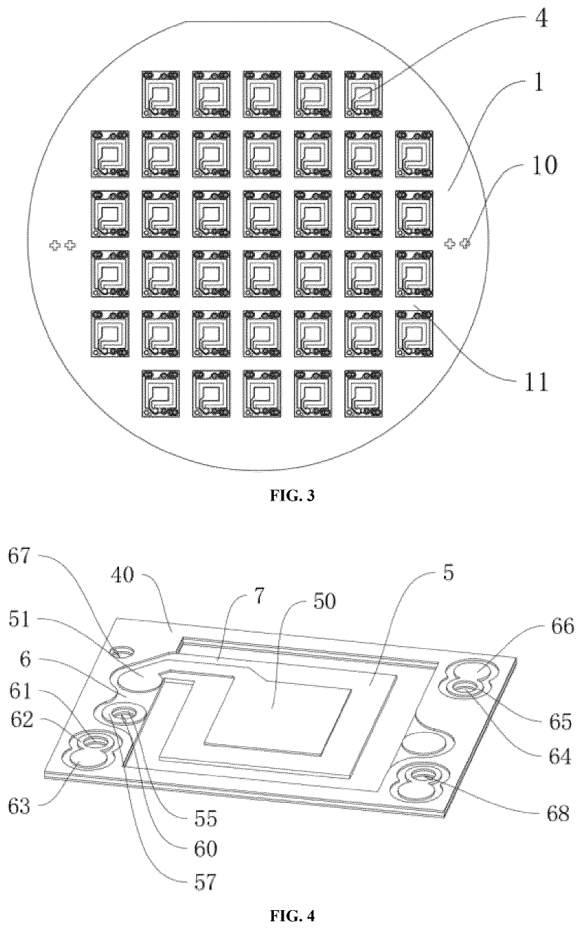

The example 1 of the present application discloses a wafer-level packaged resonator. Referring to FIG. 1 and FIG. 2, the wafer-level packaged resonator includes a second packaging substrate 2, a quartz blank 4, and a first packaging substrate 8 that are sequentially bonded and packaged. In this embodiment, the first packaging substrate 8 belongs to the upper cover plate, and the second packaging substrate 2 belongs to the basal plate. The resonator is obtained through wafer-level packaging, that is, referring to FIG. 3, the second packaging wafer, the quartz wafer 1, and the first packaging wafer are bonded and packaged sequentially during packaging.

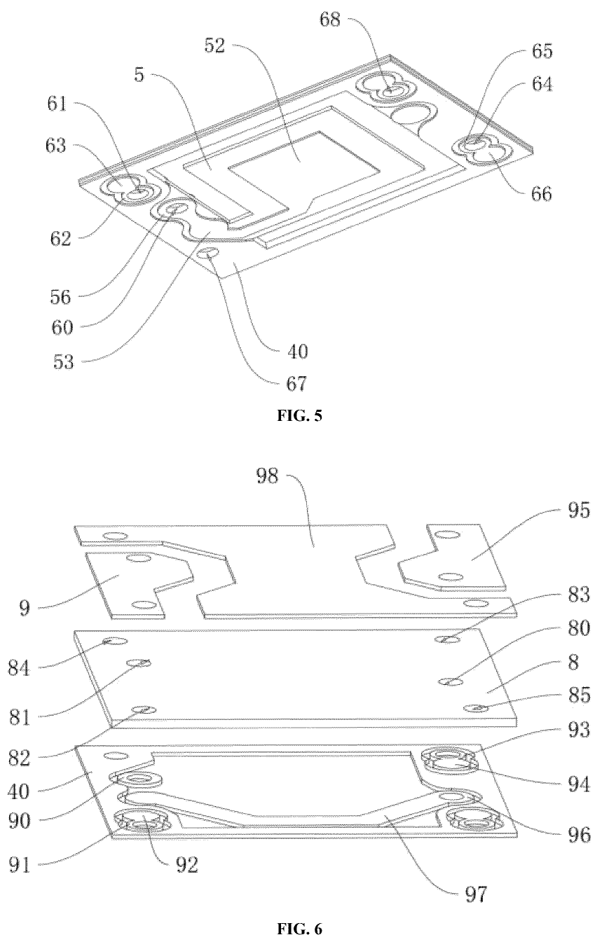

1.1. Regarding quartz blank 4, it is obtained by cutting the quartz wafer 1 after bonding and packaging the quartz wafer 1. The quartz wafer 1 includes several quartz blanks 4 arranged in arrays with cutting channels 11 reserved on the top, bottom, left, and right sides thereon. For each quartz blank 4, made of quartz, referring to FIG. 4 and FIG. 5, includes a resonant part 5, a packaging part 6, and a connecting beam 7;

The first electrode 50 and the second electrode 52 are respectively arranged on both sides of the resonant part 5. The shape of the resonant part 5 can be set according to the actual situation, specifically circular or square. In this embodiment, the resonant part 5 is square;

The middle of the packaging part 6 penetrates a space that accommodates the resonant part 5, that is, the packaging part 6 is surrounded on the periphery of the resonant part 5. The peripheral shape and the inner circle shape of the packaging part 6 can be set according to the actual situation, and in the present embodiment, the packaging part 6 is a square compatible with the resonant part 5;

The connecting beam 7 is connected between the resonant part 5 and the packaging part 6, serving as a bridge between them. The number of the connecting beams 7 can be 1, 2, 3, etc., which is depended on actual needs. In one embodiment, there are 2 connecting beams 7, which can be symmetrically arranged about the central point of the resonant part 5; In this embodiment, the connecting beam 7 is 1;

Referring to FIG. 1, both sides of the quartz blank 4 are provided with metal patterns for forming bonding and piezoelectric connections. In this embodiment, the side opposite the first packaging substrate 8 is defined as the front side, and the side opposite the second packaging substrate 2 is defined as the reverse side.

1.2. Regarding the first packaging substrate 8, it is obtained by cutting the first packaging wafer after bonding and packaging the first packaging wafer. The first packaging wafer includes several first packaging substrates 8 arranged in arrays with cutting channels 11 reserved on the top, bottom, left, and right sides on the first packaging wafer. For each first packaging substrate 8, it can be made of any one of quartz, fused quartz, or glass. In this embodiment, referring to FIG. 6, the first packaging substrate 8 is a square flat plate;

The first packaging substrate 8 is packaged on the side of the quartz blank 4 with the first electrode 50, that is, on the front side of the quartz blank 4. Both sides of the first packaging substrate 8 are provided with metal patterns for functions such as bonding, piezoelectric connection, shielding cover, etc. In this embodiment, the side opposite the quartz blank 4 is defined as the reverse side, and the other side is front.

The metal pattern on the front side of the first packaging substrate 8 includes a first solder pad 9 and a second solder pad 95. The first solder pad 9 and the second solder pad 95 are arranged with intervals on the side (front side) of the first packaging substrate 8 away from the quartz blank 4; In order to shield against external electromagnetic interference, in one embodiment, the metal pattern on the front side of the first packaging substrate 8 further includes a shielding layer 98 located on the side of the first packaging substrate 8 away from the quartz blank 4. The projection of the first electrode 50 along the thickness direction of the first packaging substrate 8 falls within the projection range of the shielding layer 98 along the thickness direction of the first packaging substrate 8.

1.3 Regarding the second packaging substrate 2, it is obtained by cutting the second packaging wafer after bonding and packaging the second packaging wafer. The second packaging wafer includes several second packaging substrates 2 arranged in arrays with cutting channels 11 reserved on the top, bottom, left, and right sides on the second packaging wafer. For each second packaging substrate 2, it can be made of any one of quartz, fused quartz, or glass. In this embodiment, the second packaging substrate 2 is a flat plate;

The second packaging substrate 2 is packaged on the side of the quartz blank 4 with the second electrode 52. Both sides of the second packaging substrate 2 are provided with metal patterns for functions such as bonding and piezoelectric connection, etc. In this embodiment, the side opposite the quartz blank 4 is defined as the front side, and the other side is reverse.

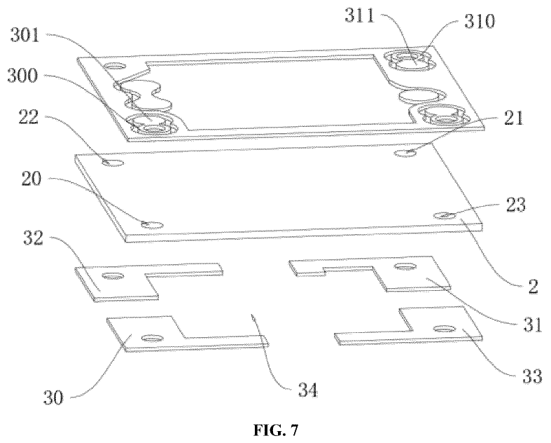

Referring to FIG. 7, a third solder pad 30 and a fourth solder pad 31 are provided on the reverse side of the second packaging substrate 2, the third solder pad 30 and the fourth solder pad 31 are set at the diagonal of the second packaging substrate 2. The third solder pad 30 is set corresponding to the first solder pad 9 in the thickness direction of the resonator, and the fourth solder pad 31 is set corresponding to the second solder pad 95 in the thickness direction of the resonator. In order to improve the soldering effect of the second packaging substrate 2, a fifth solder pad 32 and a sixth solder pad 33 are respectively arranged at the other diagonal of the reverse side of the second packaging substrate 2; In one embodiment, the middle of the third solder pad 30, the fourth solder pad 31, the fifth solder pad 32, and the sixth solder pad 33 is surrounded by a display hole 34. The projection of the second electrode 52 along the thickness direction of the resonator falls within the projection range of the display hole 34 along the thickness direction of the resonator, so that the second electrode 52 that does not block the quartz blank 4, and can realize laser fine-tuning the finished product frequency after the finished product is packaged (by adopting laser fine-tuning technology, using laser to irradiate the second electrode 52 of the quartz blank 4 from the reverse side of the second packaging substrate 2 to reach the target output frequency).

In order to achieve bonding, referring to FIG. 1 and FIG. 2, bonded metal layers 40 are provided along peripheral circumference direction on both sides of the packaging part 6, the side of the first packaging substrate 8 opposite to the packaging part 6 (reverse side), and the side of the second packaging substrate 2 opposite to the packaging part 6 (front side), and the projection of four bonded metal layers 40 overlaps along the thickness direction of the packaging part 6;

(1) In order to achieve leading the first electrode 50 out to the first solder pad 9, one position of the first solder pad 9 extends through the first packaging substrate 8 and is electrically connected with the electrode lead-out end of the first electrode 50. In one embodiment:

The electrode lead-out end of the first electrode 50 is led out to the packaging part 6 through the connecting beam 7 to form a contact point A 51, which is located inside the first bonded metal layer 40 and both are set in open-circuit. In order to improve the piezoelectric connection effect, in this embodiment, the contact point A51 is set in a disk shape;

A position of the first packaging substrate 8 opposite to the contact point A 51 (corresponding to the transition section 53 of the lead-out end of the second electrode 52) is provided with a third through-hole 81 penetrating through it. The first solder pad 9 covers the third through-hole 81 and extends along the sidewall of the third through-hole 81 to the other side of the first packaging substrate 8 to form a contact point B 90, which is piezoelectrically connected with the electrode lead-out end (contact point A 51) of the first electrode 50. In a specific embodiment, in order to improve the electric connection effect after pressing, the contact point A 51 is coaxially arranged with the third through-hole 81, and the outer radii of the contact point A 51 and the contact point B 90 are the same;

(2) In order to achieve leading the first electrode 50 out to the third solder pad 30 after to the first solder pad 9, another part of the first solder pad 9 extends sequentially through the first packaging substrate 8, the quartz blank 4 and the second packaging substrate 2, and is electrically connected with the third solder pad 30. In one embodiment:

The other part of the first packaging substrate 8 corresponding to the first solder pad 9 is provided with a fourth through-hole 82 penetrating through it. In this embodiment, the fourth through-hole 82 is located at one of the top corners of the first packaging substrate 8, promoting the fourth through-hole 82 to be set with intervals with the third through-hole 81. The first solder pad 9 extends along the sidewall of the fourth through-hole 82 to the other side of the first packaging substrate 8 to form a first annular layer 91, which is attached to the reverse of the first packaging substrate 8; The packaging part 6 corresponding to the fourth through-hole 82 is provided with a fifth through-hole 61 penetrating through it. The fifth through-hole 61 is wrapped by a second through-hole metal section 62 with [symbol] -shape along the longitudinal section of its axis, and the first annular layer 91 is piezoelectric connected with the portion of the second through-hole metal section 62 on the front side of the packaging part 6; The second packaging substrate 2 corresponding to the fourth through-hole 82 is provided with a sixth through-hole 20 penetrating through it, and the third solder pad 30 extends along the sidewall of the sixth through-hole 20 to the other side (front side) of the second packaging substrate 2 to form a second annular layer 300. The second annular layer 300 is piezoelectric connected with the portion of the second through-hole metal section 62 on the reverse side of the packaging part 6; In one embodiment, the fourth through-hole 82, the fifth through-hole 61, and the sixth through-hole 20 are coaxially arranged;

To effectively strengthen the interconnection strength of the hole-corresponding-metal and improve reliability, the sixth through-hole 20 and the fourth through-hole 82 are coaxially arranged, and the fifth through-hole 61 and the fourth through-hole 82 are set misaligned; The electrical connection with each side of the second through-hole metal section 62 also includes a first dislocation layer 63, and a pair of the first dislocation layers 63 are respectively piezoelectrically connected with the first annular layer 91 and the second annular layer 300. Specifically, the first dislocation layer 63 located on the front side of the packaging part 6 is piezoelectric connected with the first annular layer 91, and the first dislocation layer 63 located on the reverse side of the packaging part 6 is piezoelectric connected with the second annular layer 300; The electrical connection with the first annular layer 91 further includes a second dislocation layer 92, and the electrical connection with the second annular layer 300 also includes a third dislocation layer 301. The second dislocation layer 92 and the third dislocation layer 301 are respectively electrically connected with both sides of the second through-hole metal section 62; In order to further improve the effect of piezoelectric connection, the first dislocation layer 63, the second dislocation layer 92, and the third dislocation layer 301 are set as a circular shape, and are set to have the same outer radii as the first annular layer 91 and the second annular layer 300.

(3) In order to achieve leading the second electrode 52 out to the second solder pad 95, one position of the second solder pad 95 extends through the first packaging substrate 8 and is electrically connected with the electrode lead-out end of the second electrode 52. In one embodiment:

The electrode lead-out end of the second electrode 52 is led out to the packaging part 6 through the connecting beam 7, and is located inside the bonded metal layer 40 and are set in open-circuit.

The packaging part 6 is provided with a first through-hole 60 penetrating through it, and the first through-hole 60 is located on the lead-out path of the electrode lead-out end of the second electrode 52. The electrode lead-out end of the second electrode 52 includes:

A transition section 53, which is located on the reverse side of the packaging part 6 and is connected with the second electrode 52. The transition section 53 is set opposite to the electrode lead-out end of the first electrode 50. In this embodiment, the transition section 53 is disk-shaped and overlaps with the projection of the contact point A 51 along the thickness direction of the packaging part 6;

A first through-hole metal section 54, including a connecting layer 55 laid on the sidewall of the first through-hole 60, an extension layer 56 and an export layer 57 connected with both sides of the connecting layer 55 respectively. The extension layer 56 is circular and located on the reverse side of the packaging part 6, and is electrically connected with the transition section 53. The export layer 57 is circular and located on the front side of the packaging part 6;

The first packaging substrate 8 is provided with a second through-hole 80 penetrating through it, and the second through-hole 80 is located within the coverage range of the second solder pad 95. The second solder pad 95 extends along the sidewall of the second through-hole 80 to the other side of the first packaging substrate 8, forming a first lead-out end 96. In this embodiment, the first lead-out end 96 is circular and located on the reverse side of the first packaging substrate 8, extending to form a lead-out wire 97, and the other end of the lead out line 97 is opposite to the export layer 57 and is piezoelectric connected.

In order to reduce the influence of the lead-out wire 97 on the first electrode 50, the lead wire 97 is in a trapezoidal shape with the large end unsealed, while controlling the projection of the lead-out wire 97 along the thickness direction of the packaging part 6 does not intersect with the projection of the first electrode 50 along the thickness direction of the packaging part 6.

In order to achieve leading the second electrode 52 out to the fourth solder 31 after to the second solder pad 95, another part of the second solder pad 95 extends sequentially through the first packaging substrate 8, the quartz blank 4 and the second packaging substrate 2, and is electrically connected with the fourth solder 31. In one embodiment:

Another part of the first packaging substrate 8 corresponding to the second solder pad 95 is provided with a seventh through-hole 83 penetrating through it. In this embodiment, the seventh through-hole 83 is located at one of the top corners of the first packaging substrate 8, and is diagonally arranged with the fourth through-hole 82, promoting the seventh through-hole 83 to be set with intervals with the second through-hole 80. The second solder pad 95 extends along the sidewall of the seventh through-hole 83 to the other side of the first packaging substrate 8 to form a third annular layer 93 which is attached to the reverse of the first packaging substrate 8; The packaging part 6 corresponding to the seventh through-hole 83 is provided with an eighth through-hole 64 penetrating through it, and wraps around the eighth through-hole 64 is provided with a third through-hole metal section 65 with [symbol] -shape along the longitudinal section of its axis. The third annular layer 93 is piezoelectric connected with the portion of the third through-hole metal section 65 on the front side of the packaging part 6; The second packaging substrate 2 corresponding to the seventh through-hole 83 is provided with a ninth through-hole 21 penetrating through it, and the fourth solder pad 31 extends along the sidewall of the ninth through-hole 21 to the other side (front side) of the second packaging substrate 2 to form a fourth annular layer 310. The fourth annular layer 310 is piezoelectric connected with the portion of the third through-hole metal section 65 on the reverse side of the packaging part 6; In one embodiment, the seventh through-hole 83, the eighth through-hole 64, and the ninth through-hole 21 are coaxially arranged; To effectively strengthen the interconnection strength of the hole-corresponding-metal and improve reliability, the seventh through-hole 83 and the fifth through-hole 61 are coaxially arranged, and the sixth through-hole 20 and the fifth through-hole 61 are set misaligned; The electrical connection with each side of the third through-hole metal section 65 also includes a fourth dislocation layer 66, and a pair of the fourth dislocation layers 66 are respectively piezoelectrically connected with the third annular layer 93 and the fourth annular layer 310. Specifically, the fourth dislocation layer 66 located on the front side of the packaging part 6 is piezoelectric connected with the third annular layer 93, and the third dislocation layer 301 located on the reverse side of the packaging part 6 is piezoelectric connected with the fourth annular layer 310; The electrical connection with the third annular layer 93 further includes a fifth dislocation layer 94, and the electrical connection with the fourth annular layer 310 also includes a sixth dislocation layer 311. The fifth dislocation layer 94 and the sixth dislocation layer 311 are respectively electrically connected with both sides of the third through-hole metal section 65; In order to further improve the effect of piezoelectric connection, the fourth dislocation layer 66, the fifth dislocation layer 94, and the sixth dislocation layer 311 are set as a circular shape, and are set to have the same outer radii as the third annular layer 93 and the fourth annular layer 310.

(5) In order to improve the overall symmetry of the device and the bonding effect, in another embodiment, a first thru-hole 84 and a second thru-hole 85 are respectively penetrated through the other diagonal of the first packaging substrate 8. The first thru-hole 84 is close to a diagonal corner of the resonator with contact point A 51 and the contact point A 51 is coaxial with the first thru-hole 84. The first thru-hole 84 sequentially penetrates through the packaging part 6. The second packaging substrate 2 is provided with a third thru-hole 67 and a fourth thru-hole 22, all the first thru-hole 84, the third thru-hole 67 and the fourth thru-hole 22 are set coaxial, and a metal layer is provided on the inner wall, so that the shielding cover is connected with the fifth solder pad 32; Similarly, sequentially penetrate through the packaging part 6, the second packaging substrate 2 is provided with a fifth thru-hole 68 and a sixth thru-hole 23. The second thru-hole 85 and the sixth thru-hole 23 are coaxial, while the second through hole and the fourth through hole 22 are set misaligned. The shielding cover is connected with the sixth solder pad 33 through cooperative with the setting of metal layer.

(6) In order to improve the accuracy of alignment of the second packaging wafer, the quartz wafer 1, and the first packaging wafer during the bonding and packaging process, there are two alignment marks 10 on the left and right edges of the second packaging wafer, the quartz wafer 1, and the first packaging wafer, respectively. During packaging, the alignment mark 10 of quartz wafer 1 corresponds to the alignment marks 10 of the first packaging wafer and the second packaging wafer, respectively.

The implementation principle of Example 1 of the present application is: The quartz blank 4, the first packaging substrate 8, and the second packaging substrate 2 are bonded in three layers to obtain resonator products, whose electrical connection method is as follows:
first electrode 50→contact point A 51→contact point B 90→third through-hole 81→first solder pad 9→fourth through-hole 82→first annular layer 91→second through-hole metal section 62 (fifth through-hole 61)→second annular layer 300→sixth through-hole 20→third solder pad 30, thus realizing the electrical connection of the first electrode 50—the first solder pad 9—the third solder pad 30 of the quartz wafer 4.

second electrode 52→transition section 53→first through-hole metal section 54 (first through-hole 60)→lead-out wire 97→first lead-out end 96→second through-hole 80→second solder pad 95→seventh through-hole 83→third annular layer 93→third through-hole metal section 65 (eighth through-hole 64)→fourth annular layer 310→ninth through-hole 21→fourth solder pad 31, thereby achieving the electrical connection of the second electrode 52—second solder pad 95—and fourth solder pad 31 of the quartz wafer 4.

When used as a resonator, the first electrode 50 and the second electrode 52 of the resonator are connected to a specific circuit through the third solder pad 30 and the fourth solder pad 31, respectively. A voltage is generated between the first electrode 50 and the second electrode 52, and the resonant part 5 vibrates under the piezoelectric effect, outputs specific frequency to achieve the resonator function.

### Example 2

The example 2 of the present application discloses a preparation method of the wafer-level packaged resonator. Referring to FIG. 3, the method includes the following steps:

S1, Prepare the blank wafer;

Step 1.1: Deposit an etch-resistant metal layer material consisting of Cr/Au or Ti/Au on the surface of the blank wafer body by magnetron sputtering, electroplating or evaporation;

Step 1.2: Form a photoresist film on the surface of the blank wafer body by spin coating or spraying, form an exposure pattern by photolithography photomask exposure, and develop to remove the unexposed area pattern;

Perform the same process on the lower surface of the blank wafer body to produce a symmetrical pattern on the reverse side;

Step 1.3: Use the corresponding metal etching solution to remove the metal layer in the area not protected by the photoresist.

Step 1.4: Produce corresponding holes by wet etching, dry etching or laser etching on the blank wafer body, and obtain the vibration part, the packaging part 6, and the connecting beam 7;

Step 1.5: Perform metal electrode coating processing on the blank wafer body, using magnetron sputtering, electroplating, or evaporation methods to deposit metal materials (optionally Cr, Ti, Ni, Ru, Au) on the upper and lower surfaces of the blank wafer body;

Step 1.6: Form a photoresist film on the upper and lower surfaces of the blank wafer body by spin coating or spraying, form an exposure pattern by photolithography photomask exposure, and develop to remove the unexposed area pattern;

Perform the same process on the lower surface of the blank wafer body to produce a symmetrical pattern on the reverse side;

Step 1.7: Use the corresponding metal etching solution to remove the metal layer in the area not protected by the photoresist, and for each quartz blank 4, a front side metal pattern, a reverse side metal pattern, and a metal layer penetrating the corresponding hole are formed;

As shown in FIG. 3, while etching to obtain the corresponding holes, the alignment marks 10 are also made, forming several quartz blanks 4 arranged in arrays on the blank wafer body, with cutting channels 11 reserved around each quartz blank 4;

Step 1.8: Use the de-photoresist solution to remove the photoresist film, thus completing the production of the blank wafer.

S2, Prepare the first packaging wafer;

Step 2.1: Grind and polish the upper and lower surfaces of the first packaging wafer body sequentially;

Deposit an etch-resistant metal layer material consisting of Cr/Au or Ti/Au on the surface of the first packaging wafer body by magnetron sputtering, electroplating or evaporation;

Step 2.2: Form a photoresist film on the surface of the first packaging wafer body by spin coating or spraying, form an exposure pattern by photolithography photomask exposure, and develop to remove the unexposed area pattern;

Perform the same process on the lower surface of the first packaging wafer body to produce a symmetrical pattern on the reverse side;

Step 2.3: Use the corresponding metal etching solution to remove the metal layer in the area not protected by the photoresist;

Step 2.4: Produce corresponding holes by wet etching, dry etching or laser etching on the first packaging wafer body;

Step 2.5: Use the de-photoresist solution to remove the photoresist film, use the corresponding metal etching solution to remove all metals remaining on the first packaging wafer body;

Step 2.6: Perform metal electrode coating processing on the first packaging wafer body, using magnetron sputtering, electroplating, or evaporation methods to deposit metal materials (optionally Cr, Ti, Ni, Ru, Cu, Au) on the upper and lower surfaces of the first packaging wafer body;

Step 2.7: Form a photoresist film on the upper and lower surfaces of the first packaging wafer body by spin coating or spraying, form an exposure pattern by photolithography photomask exposure, and develop to remove the unexposed area pattern;

Perform the same process on the lower surface of the first packaging wafer body to produce a symmetrical pattern on the reverse side;

Step 2.8: Use the corresponding metal etching solution to remove the metal layer in the area not protected by the photoresist, and for each first packaging substrate 8, a front side metal pattern, a reverse side metal pattern, and a metal layer penetrating the corresponding hole are formed, thus several first packaging substrates 8 arranged in arrays on the first packaging wafer are formed;

While etching to obtain the corresponding holes, the alignment marks 10 are also made, forming several first packaging substrates 8 arranged in arrays on the first packaging wafer body, with cutting channels 11 reserved around single packaging substrate 8;

Step 2.9: Use the de-photoresist solution to remove the photoresist film, thus completing the production of the first packaging wafer.

S3, Prepare the second packaging wafer

Step 3.1: Grind and polish the upper and lower surfaces of the second packaging wafer body sequentially, then deposit an etch-resistant metal layer material consisting of Cr/Au or Ti/Au on the surface of the second packaging wafer body by magnetron sputtering, electroplating or evaporation;

Step 3.2: Form a photoresist film on the surface of the second packaging wafer body by spin coating or spraying, form an exposure pattern by photolithography photomask exposure, and develop to remove the unexposed area pattern;

Perform the same process on the lower surface of the second packaging wafer body to produce a symmetrical pattern on the reverse side;

Step 3.3: Use the corresponding metal etching solution to remove the metal layer in the area not protected by the photoresist;

Step 3.4: Produce corresponding holes by wet etching, dry etching or laser etching on the second packaging wafer body;

Step 3.5: Use the de-photoresist solution to remove the photoresist film, use the corresponding metal etching solution to remove all metals remaining on the second packaging wafer body;

Step 3.6: Perform metal electrode coating processing on the second packaging wafer body, using magnetron sputtering, electroplating, or evaporation methods to deposit metal materials (optionally Cr, Ti, Ni, Ru, Cu, Au) on the upper and lower surfaces of the second packaging wafer body;

Step 3.7: Form a photoresist film on the upper and lower surfaces of the second packaging wafer body by spin coating or spraying, form an exposure pattern by photolithography photomask exposure, and develop to remove the unexposed area pattern;

Perform the same process on the lower surface of the second packaging wafer body to produce a symmetrical pattern on the reverse side;

Step 3.8: Use the corresponding metal etching solution to remove the metal layer in the area not protected by the photoresist, and for each second packaging substrate 2, a front side metal pattern, a reverse side metal pattern, and a metal layer penetrating the corresponding hole are formed, thus several second packaging substrates 2 arranged in arrays on the second packaging wafer body are formed;

Step 3.9: Use the de-photoresist solution to remove the photoresist film, thus completing the production of the second packaging wafer.

S4, Stack and bond the second packaging wafer, the blank wafer, and the first packaging wafer in sequence and then cut, including the following steps:

Step 4.1: Adopting the alignment marking method, stack the above prepared first packaging wafer, blank wafer, and second packaging wafer in sequence, and under vacuum environment, the three wafers are formed into an integral by room temperature or a hot pressure bonding process, realizing the vacuum packaging of the wafer while conducting the wafer electrode to the solder pad;

Step 4.2: Adopting laser fine-tuning technology, using laser to irradiate the wafer electrode from the reverse side of the second packaging wafer to adjust the electrode quality to reach the target output frequency;

Step 4.3: The individual devices are cut and separated along the along the perimeter of the resonator unit by using a blade or laser cutting technology, thereby achieving the production of surface-mount wafer-level packaged resonators.

### Example 3

The example 3 of the present application discloses a preparation method of the wafer-level packaged resonator. Different from Example 2 is that between step 1.4 and step 1.5 further includes: Thin the vibration part and the connecting beam 7 by processing technology of wet etching, dry etching or laser etching to reach a predetermined frequency, while reserve vibration space for the wafer.

### Example 4

The example 3 of the present application discloses an electronic equipment, including the wafer-level packaged resonator described above. The electronic equipment can specifically be a key component in an electronic equipment such as oscillator, filter, etc., as well as any electronic equipment that including wafer-level packaged resonators.

The examples of this specific embodiments are all preferred examples of the present application, and the scope of protection of the present application is not limited accordingly, where the same parts are denoted by the same reference numerals. Therefore, all equivalent changes made according to the structure, shape and principle of the present application should be included in the scope of protection of the present application.

What is claimed is:

1. A wafer-level packaged resonator, comprising:
a quartz blank, both sides of which are provided with a first electrode and a second electrode respectively;
a first packaging substrate, packaged on a side of the quartz blank provided with the first electrode, and a first solder pad and a second solder pad are provided with intervals on a side of the first packaging substrate away from the quartz blank;
a second packaging substrate, packaged on an other side of the quartz blank, and a third solder pad and a fourth solder pad are provided on a side of the second packaging substrate away from the quartz blank;
wherein one position of the first solder pad extends through the first packaging substrate and is electrically connected with an electrode lead-out end of the first electrode, and another position of the first solder pad extends through the first packaging substrate, the quartz blank, and second packaging substrate in sequence and is electrically connected with the third solder pad;
one position of the second solder pad extends through the first packaging substrate and is electrically connected with an electrode lead-out end of the second electrode, and another position of the second solder pad extends through the first packaging substrate, the quartz blank, and second packaging substrate in sequence and is electrically connected with the fourth solder pad;
the quartz blank comprises a resonant part, a packaging part surrounded on the periphery of the resonant part, and a connecting beam between the resonant part and the packaging part, and the first electrode and the second electrode are respectively arranged on both sides of the resonant part;
both sides of the packaging part, a side of the first packaging substrate opposite to the packaging part, and a side of the second packaging substrate opposite to the packaging part are provided with bonded metal layers, and a projection of the bonded metal layers overlaps along a thickness direction of the packaging part;
the electrode lead-out end of the first electrode and the electrode lead-out end of the second electrode are both led out to the packaging part through the connecting beam, and are located inside the bonded metal layer.

2. The wafer-level packaged resonator of claim 1, wherein
the packaging part is provided with a first through-hole penetrating through it, and the first through-hole is located on a lead-out path of the electrode lead-out end of the second electrode, the electrode lead-out end of the second electrode comprises:
a transition section, provided opposite to the electrode lead-out end of the first electrode;
a first through-hole metal section, comprising a connecting layer laid on a sidewall of the first through-hole, an extension layer and an export layer connected with both sides of the connecting layer respectively; the extension layer is electrically connected with the transition section.

3. The wafer-level packaged resonator of claim 2, wherein the first packaging substrate is provided with a second through-hole penetrating through it, and the second solder pad extends along a sidewall of the second through-hole to another side of the first packaging substrate to form a first lead-out end; the first lead-out end extends to form a lead-out wire, and an other end of the lead-out wire is opposite to the export layer and is piezoelectric connected.

4. The wafer-level packaged resonator of claim 3, wherein a position of the first packaging substrate opposite to the transition section is provided with a third through-hole penetrating through it, and the first solder pad extends along a sidewall of the third through-hole to an other side of the first packaging substrate to be piezoelectrically connected with the electrode lead-out end of the first electrode.

5. The wafer-level packaged resonator of claim 4, wherein another part of the first packaging substrate corresponding to the first solder pad is provided with a fourth through-hole penetrating through it, and the first solder pad extends along a sidewall of the fourth through-hole to another side of the first packaging substrate to form a first annular layer;
the packaging part corresponding to the fourth through-hole is provided with a fifth through-hole penetrating through it, and wraps around the fifth through-hole is provided with a second through-hole metal section; the first annular layer is electrically connected with the second through-hole metal section;
the second packaging substrate corresponding to the fourth through-hole is provided with a sixth through-hole penetrating through it, and the third solder pad extends along a sidewall of the sixth through-hole to another side of the second packaging substrate to form a second annular layer;
the second annular layer is electrically connected with the second through-hole metal section;
and/or,
another part of the first packaging substrate corresponding to the second solder pad is provided with a seventh through-hole penetrating through it, and the second solder pad extends along a sidewall of the seventh through-hole to another side of the first packaging substrate to form a third annular layer; the packaging part corresponding to the seventh through-hole is provided with an eighth through-hole penetrating through it, and wraps around the eighth through-hole is provided with a third through-hole metal section, and the third annular layer is electrically connected with the third through-hole metal section; the second packaging substrate corresponding to the seventh through-hole is provided with a ninth through-hole penetrating through it, and the fourth solder pad extends along the sidewall of the ninth through-hole to another side of the second packaging substrate to form a fourth annular layer, the fourth annular layer is electrically connected with the third through-hole metal section.

6. The wafer-level packaged resonator of claim 5, wherein when the first solder pad is provided with the fourth through-hole penetrating through it, the sixth through-hole and the fourth through-hole are coaxially arranged, the fifth through-hole and the fourth through-hole are set misaligned; electrical connection with each side of the second through-hole metal section also comprises a first dislocation layer, and a pair of the first dislocation layers are respectively piezoelectrically connected with the first annular layer and the second annular layer; electrical connection with the first annular layer further comprises a second dislocation layer, and electrical connection with the second annular layer also comprises a third dislocation layer; the second dislocation layer and the third dislocation layer are respectively electrically connected with both sides of the second through-hole metal section;
when the second solder pad is provided with the seventh through-hole penetrating through it, the seventh through-hole and the fifth through-hole are coaxially arranged, the sixth through-hole and the fifth through-hole are set misaligned; electrical connection with each side of the third through-hole metal section also comprises a fourth dislocation layer, and a pair of the fourth dislocation layers are respectively piezoelectrically connected with the third annular layer and the fourth annular layer; electrical connection with the third annular layer further comprises a fifth dislocation layer, and electrical connection with the fourth annular layer also comprises a sixth dislocation layer; the fifth dislocation layer and the sixth dislocation layer are respectively electrically connected with both sides of the third through-hole metal section.

7. The wafer-level packaged resonator of claim 3, wherein the wafer-level packaged resonator further comprises a shielding layer arranged on a side of the first packaging substrate away from the quartz blank, and a projection of the first electrode along a thickness direction of the first packaging substrate falls within a projection range of the shielding layer along a thickness direction of the first packaging substrate.

8. A preparation method of the wafer-level packaged resonator of claim 1, comprising the following steps:
prepare a blank wafer, wherein the blank wafer comprises a plurality of array-arranged quartz blanks;
prepare a first packaging wafer, wherein the first packaging wafer comprises a plurality of the first packaging substrates;
prepare a second packaging wafer, wherein the second packaging wafer comprises a plurality of the second packaging substrates, wherein the first packaging substrates and the second packaging substrates correspond one-to-one with several quartz blanks, respectively;
stack and bond the second packaging wafer, the blank wafer, and the first packaging wafer in sequence and then cut.

9. An electronic equipment comprising the wafer-level packaged resonator of claim 1.
